(19) United States
(12) Patent Application Publication
(10) Pub. No.: US 2011/0057710 A1
(43) Pub. Date: Mar. 10, 2011

(54) Semiconductor integrated circuit

(75) Inventor: Toshiaki Terayama, Kanagawa (JP)

(73) Assignee: Renesas Electronics Corporation, Kawasaki (JP)

(21) Appl. No.: 12/805,653

(22) Filed: Aug. 11, 2010

(30) Foreign Application Priority Data
Sep. 7, 2009 (JP) 2009-205580

(51) Int. Cl. H03K 17/00

(52) U.S. Cl. 327/365

(57) ABSTRACT

A semiconductor integrated circuit 1 according to an exemplary embodiment of the present invention is including: a first wire that is supplied with a clock signal; a second wire that is supplied with the clock signal, the clock signal is supplied or shut off independently of the clock signal supplied to the first wire; a first area that includes a first mesh shape wire supplied with the clock signal from the first wire; a second area that includes a second mesh shape wire supplied with the clock signal from the second wire; and a switching circuit that switches to a conduction or a shutoff of a signal transmitted between the first mesh shape wire and the second mesh shape wire.

### INCORPORATION BY REFERENCE

This application is based upon and claims the benefit of priority from Japanese patent application No. 2009-205580, filed on Sep. 7, 2009, the disclosure of which is incorporated herein in its entirety by reference.

### BACKGROUND

1. Field of the Invention

The present invention relates to a semiconductor integrated circuit, and more particularly, a technique to reduce the clock skew and the power consumption of the semiconductor integrated circuit.

2. Description of Related Art

In a semiconductor integrated circuit, there is a major problem to reduce the clock skew occurred by difference of wiring length from a source of a clock signal to circuits which receive the clock signal, wiring resistance and so on. If the clock skew is occurred, a semiconductor integrated circuit malfunctions by that the deviation in operation timing of each of circuits supplied with a clock signal is occurred.

Japanese Unexamined Patent Application Publication No. 2007-214334 discloses a technique to reduce the clock skew like this. Japanese Unexamined Patent Application Publication No. 2007-214334 discloses a semiconductor integrated circuit includes a first power supply area driven by a first power supply, and a second power supply area driven by a second power supply. In the semiconductor integrated circuit, a input terminal of the clock buffer of the nth stage driven by the second power supply connects to output terminal of the clock buffer of the (n−1)th stage driven by the first power supply. This enables to reduce the clock skew of the clock signal between different power supply areas.

### SUMMARY

There is a semiconductor integrated circuit that includes areas in each of which the electric power can be independently supplied or shut off as described in Japanese Unexamined Patent Application Publication No. 2007-214334. The semiconductor integrated circuit is mounted on an information processing device each as microcomputer, AV (Audio Visual) device, mobile phone and so on. FIG. 5 shows an example of a semiconductor integrated circuit that includes areas in each of which the electric power can be independently supplied or shut off. FIG. 5 is not a “prior art” figure, because it is drafted by the inventor in order to explain a problem discovered by the inventor.

A semiconductor integrated circuit 100 shown in FIG. 5 includes an Always-ON area 102 and a power supply separation area 103. When the semiconductor integrated circuit 100 operates, the Always-ON area 102 is always supplied with the power supply. Even when the semiconductor integrated circuit 100 operates, the power supply separation area 103 in which the power supply is supplied or shut off independently of the Always-ON area 102. For example, the semiconductor integrated circuit 100 is mounted in a mobile phone, and the power supply separation area 103 in which a circuit that carries out a processing of a camera function is laid out. This enables to reduce the power consumption by shutting off the power supply supplied to the power supply separation area 103, when the camera function is not started and thus it is necessary to drive the circuit that carries out the processing of the camera function.

The semiconductor integrated circuit 100 includes a wire 110 that supplies clock meshes 121 and 131 with a clock signal output from a clock root buffer 111. The wire 110 (hereafter, referred to as a “clock tree”) that wiring length is adjusted by being formed into a tree shape. The clock tree 110 includes clock buffers 112, 113a, 113b, 114a-114p, 115, 116a, 116b, and 117a-117p to adjust the phase of the clock signal transmitted. The semiconductor integrated circuit 100 adjusts the degree of the delay of the clock signal supplied with each of the clock meshes 121 and 131 by these clock buffers.

Always-ON area 102 includes a wire 121. The wire 121 supplies a circuit (hereafter, referred to as a “drive target circuit”), in the area 102, with the clock signal supplied from the clock tree 110. The wire 121 is a mesh shape wire to reduce the variation of the clock signal supplied to the drive target circuit. The power supply separation area 103 includes clock mesh 131. The clock mesh 131 supplies the drive target circuits in the area 103 with the clock signal supplied from the clock tree 110.

When it is necessary to drive the drive target circuits of the power supply area 103, the semiconductor integrated circuit 100 shuts off the clock signal supplied from the clock tree 110 to the power supply separation area 103, and shuts off the power supply supplied to the power supply separation area 103. This enables to eliminate the consumption of the power supply to supply the drive target circuits of the power supply separation area 103 with the clock signal and the power supply to supply the drive target circuits of the power supply separation area 103 with the power supply, thus reduce the power consumption.

As explained above, the semiconductor integrated circuit 100 can reduce the clock skew of each of the areas 102 and 103. Furthermore, the semiconductor integrated circuit 100 can reduce the power consumption by shutting off the clock signal and the power supply supplied to the power supply separation area 103. However, in the subsequent stage of the clock root buffer 111, the clock tree 110 branches into each of the areas 102 and 103, thus the clock tree 110 is formed separate wire. Thus, there is a problem that the clock skew is occurred between the area 102 and the area 103. That is, the semiconductor integrated circuit 100 shown in FIG. 5 has a problem that the power consumption can be reduced but the clock skew is occurred between the area 102 and the area 103.

Note that, as explained in the related arts, a technique disclosed in Japanese Unexamined Patent Application Publication No. 2007-214334 that reduces the clock skew of the clock signal transmitted between different power supply areas by connecting input terminal of clock buffer of the nth stage, the last stage, to output terminal of clock buffer of the (n−1)th stage of the clock tree. However, a technique disclosed in Japanese Unexamined Patent Application Publication No. 2007-214334 has possibility that the variation of the clock signal is occurred before the clock signal arrives at the mesh shape wire. Consequently, a technique disclosed in Japanese Unexamined Patent Application Publication No. 2007-214334 cannot enough reduce the clock skew.

Next, FIG. 6 shows a semiconductor integrated circuit that enables to reduce the clock skew between an Always-ON area 202 and a power supply separation area 203. FIG. 6 is not a “prior art” figure, because it is drafted by the inventor in order to explain a problem discovered by the inventor.

The semiconductor integrated circuit 200 shown in FIG. 6 includes the Always-ON area 202 and the power supply separation area 203. The semiconductor integrated circuit 200 includes a clock tree 210 that supplies a clock mesh 204 with a clock signal output from a clock root buffer 211. The clock tree 210 includes a clock buffer 212a, 212b, and 213a-213p. The semiconductor integrated circuit 200 adjusts the degree of the delay of the clock signal supplied to the clock mesh 204 by these clock buffers.

In the semiconductor integrated circuit 200, the clock mesh 204 is composed to straddle the Always-ON area 202 and the power supply separation area 203. Thus, the semiconductor integrated circuit 200 can reduce the clock skew between the Always-ON area 202 and the power supply separation area 203.

The clock mesh 204 supplies a drive target circuit in the Always-ON area 202 and the power supply separation area 203 with the clock signal supplied from the clock tree 210. Thus, the drive target circuit included the Always-ON area 202 and the power supply separation area 203 is supplied the clock signal that the clock skew is reduced from the same clock mesh 204.

When it is necessary to drive the drive target circuit of the power supply separation area 203, the semiconductor integrated circuit 200 shown in FIG. 6 shuts off the power supply supplied to the power supply separation area 203, and shuts off the clock signal supplied from the clock tree 210 to the power supply separation area 203 to reduce the power consumption. However, even so, the power supply separation area 203 is supplied with the clock signal from the Always-ON area 202 via the clock mesh 204. As a result, the power supply separation area 203 is supplied with the normally unnecessary clock signal, thus there is a problem that the extra power supply is consumed. That is, there is a problem that the semiconductor integrated circuit 200 shown in FIG. 6 can reduce the clock skew between the area 202 and the area 203, but cannot enough reduce the power consumption.

The abovementioned problem is occurred not only a semiconductor integrated circuit that includes areas in which the power supply is independently supplied or shut off. For example, in the semiconductor integrated circuit 100 shown FIG. 5, even if the Always-ON area 102 and the power supply separation area 103 are not independently supplied with or shut off from the power supply, the abovementioned problem is occurred. That is, as described above, there is a similar problem not only a semiconductor integrated circuit that the areas in each of which the clock signal and the power supply are independently supplied or shut off but also a semiconductor integrated circuit that the areas in each of which the clock signal is independently supplied or shut off.

For example, in the semiconductor integrated circuit 100 shown FIG. 5, even if the supply or the shutoff of the power supply are not independently controlled for each of the areas 202 and 203, when it is necessary to drive the drive target circuit of one area, the clock signal supplied from the clock tree 110 to the area is shut off. In doing so, it is possible to eliminate the power consumption to supply the clock signal, thus reduce the power consumption.

However, even if this semiconductor integrated circuit, in the subsequent stage of the clock root buffer, the clock tree that transmits the clock signal branches into each of the areas, thus the clock tree is formed into separate wire as with the semiconductor integrated circuit 100 shown FIG. 5. Thus, there is problem that the clock skew is occurred between each of the areas. That is, there is a problem that the power consumption can be reduced but the clock skew is occurred between each of the areas as with the semiconductor integrated circuit 100 shown FIG. 5.

Furthermore, in the semiconductor integrated circuit 200 shown FIG. 6, even if the Always-ON area 202 and the power supply separation area 203 are not independently supplied with or shut off from the power supply, there is similar problem.

That is, in the semiconductor integrated circuit 200 shown FIG. 6, regardless of whether or not the supply or the shutoff of the power supply is independently controlled for each of the areas 202 and 203, even when the clock signal supplied from the clock tree 210 to the area 203 is shut off as that driving the drive target circuit of the area 203 is unnecessary, the area 203 is also supplied with the clock signal from the other area 202 via the clock mesh. As a result, the power supply separation area 203 is supplied the normally unnecessary clock signal, thus there is a problem that the extra power is consumed.

As explained above, in a semiconductor integrated circuit includes areas in which the power supply is independently supplied or shut off, there is a problem to do not reduce the clock skew and do not reduce the power consumption.

A first exemplary aspect of the present invention is a semiconductor integrated circuit including: a first wire that is supplied with a clock signal; a second wire that is supplied with the clock signal, the clock signal is supplied or shut off independently of the clock signal supplied to the first wire; a first area that includes a first mesh shape wire supplied with the clock signal from the first wire; a second area that includes a second mesh shape wire supplied with the clock signal from the second wire; and a switching circuit that switches to a conduction or a shutoff of a signal transmitted between the first mesh shape wire and the second mesh shape wire.

Thus, when the first area and the second area are supplied with the clock signal, it is possible to reduce the clock skew between the first area and the second area by conducting between the first mesh shape wire and the second mesh shape wire. Furthermore, when one of the first area and the second is not supplied with the clock signal, between the first mesh shape wire and the second mesh shape wire is shut off. This prevents that the clock signal is supplied to the area to should not be supplied the clock signal, thus it is possible to reduce the power consumption.

In accordance with each of the above-described exemplary aspects, in a semiconductor integrated circuit includes areas in which the power supply is independently supplied or shut off, the present invention provide a semiconductor integrated circuit that is capable of reducing the clock skew and reducing the power consumption.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a configuration diagram of a semiconductor integrated circuit in accordance with a first exemplary embodiment of the present invention;

FIG. 2 is a configuration diagram of a semiconductor integrated circuit in accordance with a second exemplary embodiment of the present invention;

FIG. 3 is a configuration diagram of a semiconductor integrated circuit in accordance with a third exemplary embodiment of the present invention;

FIG. 4 is a configuration diagram of a semiconductor integrated circuit in accordance with a fourth exemplary embodiment of the present invention;

FIG. 5 is a diagram showing an example of a semiconductor integrated circuit that includes areas in each of which the power supply is independently supplied or shut off;

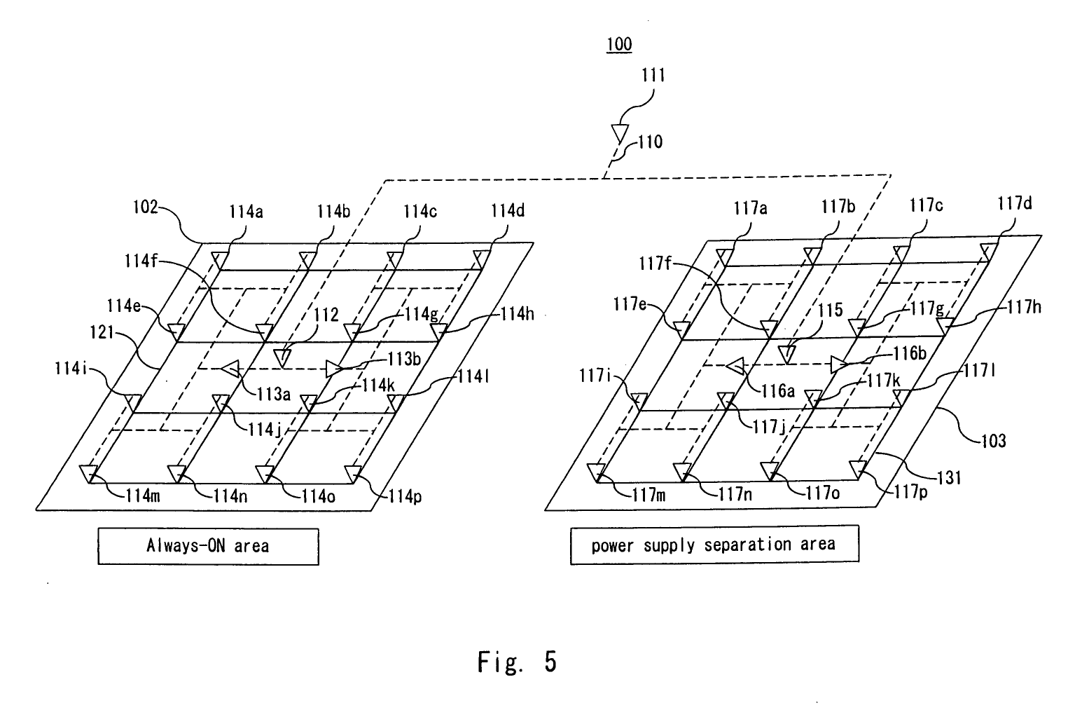

FIG. 6 is a diagram showing another example of a semiconductor integrated circuit that includes areas in each of which the power supply is independently supplied or shut off.

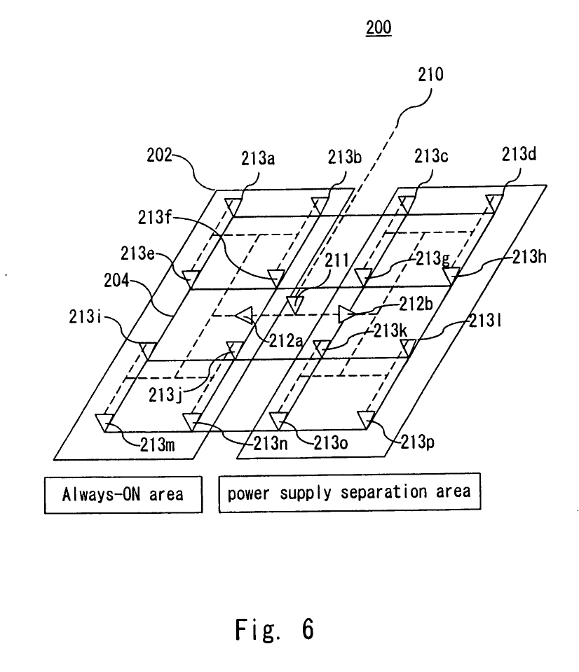

### DETAILED DESCRIPTION OF THE EXEMPLARY EMBODIMENTS

### First Exemplary Embodiment

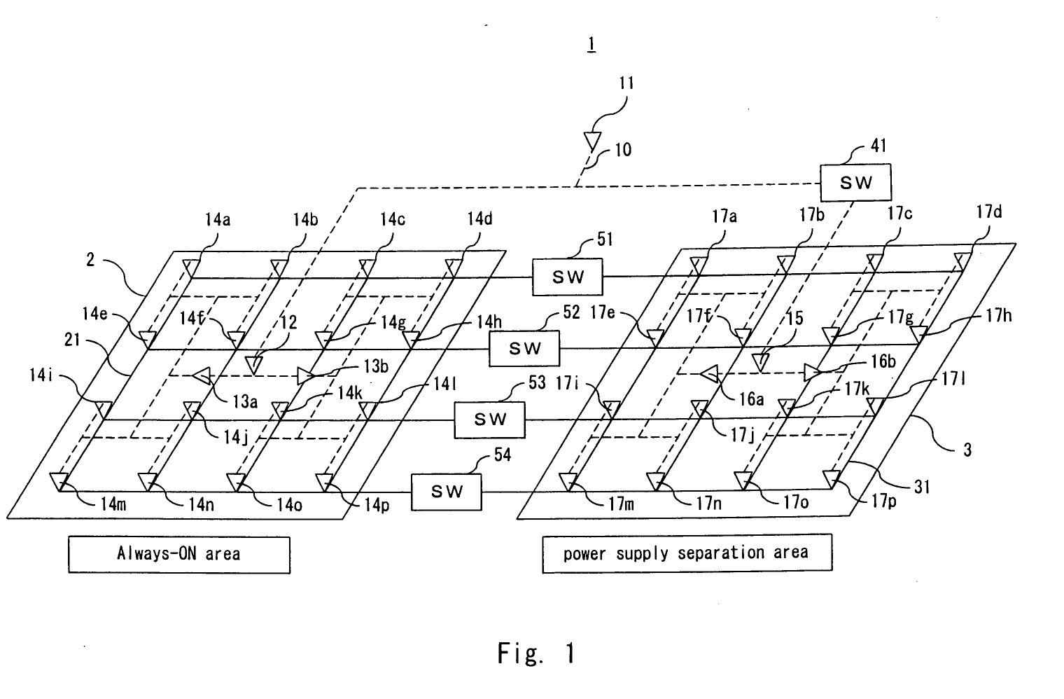

A configuration of a semiconductor integrated circuit in accordance with a first exemplary embodiment of the present invention is explained with reference to FIG. 1. FIG. 1 is a configuration diagram of a semiconductor integrated circuit in accordance with a first exemplary embodiment of the present invention.

A semiconductor integrated circuit 1 includes a Always-ON area 2, a power supply separation area 3, a clock tree 10, a clock root buffer 11, a switch (hereafter, referred to as a “clock tree”) 41 and switches 51, 52, 53, and 54. The clock tree 10 includes the clock root buffer 11.

The clock tree 10 branches in the subsequent stage of the clock root buffer 11. The clock tree 10, in a tree shape wire (hereafter, referred to as a “branch”) in the Always-ON area 2, includes a clock buffer 12 in the next stage of the clock root buffer 11, clock buffers 13a and 13b in the next stage of the clock buffer 12, and clock buffers 14a-14p in the next stage of the clock buffer 13. The clock buffers 13a and 13b are referred to as a “clock buffer 13”, and the clock buffers 14a-14p are referred to as a “clock buffer 14”.

The clock tree 10, in a branch in the power supply separation area 3, includes a clock buffer 15 in the next stage of the clock root buffer 11, clock buffers 16a and 16b the next stage of the clock buffer 15, and clock buffers 17a-17p of the next stage of the clock buffers 16. The clock buffers 16a and 16b are referred to as “clock buffers 16”, the clock buffers 17a-17p are referred to as “clock buffers 17”. Note that, branch corresponds to the first wire or the second wire.

Next, the elements of a semiconductor integrated circuit in accordance with a first exemplary embodiment of the present invention are explained.

The Always-ON area 2 is area in which the power supply is supplied or shut off. The Always-ON area 2 includes a drive target circuit (not shown) that is always driven by being supplied with the power supply, when the semiconductor integrated circuit 1 operates.

The power supply separation area 3 includes a drive target circuit that is driven by being supplied with the power supply independently of the Always-ON area 102. The power supply separation area 3 is shut off from the power supply, when it is necessary to drive the drive target circuit included in the power supply separation area 3.

The clock root buffer 11 supplies the clock tree 10 with a clock signal.

The clock tree 10 supplies the clock mesh 21 with the clock signal supplied from the clock root buffer 11 via the clock buffers 12, 13 and 14. The clock tree 10 supplies the clock mesh 31 with the clock signal supplied from the clock root buffer 11 via the clock buffers 15, 16 and 17. Each of the clock buffers 12-17 is a circuit that adjusts the phase of the clock signal transmitted by the clock tree 10.

The clock mesh 21 supplies the drive target circuit included in the Always-ON area 2 with the clock signal supplied from the clock buffer 14.

The clock mesh 31 supplies the drive target circuit included in the power supply separation area 3 with the clock signal supplied from the clock buffers 17.

Note that, specifically, the clock meshes 21 and 31 are a wire laid on at least one of the wiring layers of a chip. The drive target circuit consists of a circuit elements laid on an element layer that is a lower layer of the wiring layer. That is, the clock meshes 21 and 31 drive the drive target circuits by supplying these circuit elements with the clock signal.

The SW 41 is a circuit that switches to the supply or the shutoff of the power supply supplied to the clock mesh 31. The SW 41 shuts off the clock signal supplied to the clock mesh 31, when it is necessary to drive the drive target circuit of the power supply separation area 3. That is, the Always-ON area 2 and the power supply separation area 3 in which the power supply are independently supplied or shut off.

Each of the SWs 51-54 is a circuit that switches to the conduction or the shutoff of the clock signal transmitted between the clock mesh 21 and the clock mesh 31. The SWs 51-54 correspond to the switching circuit.

Next, a processing of a semiconductor integrated circuit in accordance with a first exemplary embodiment of the present invention is explained.

When the Always-ON area 2 and the power supply separation area 3 are driven, the semiconductor integrated circuit 1 supplies the Always-ON area 2 and the power supply separation area 3 with the power supply. Furthermore, the semiconductor integrated circuit 1 supplies the Always-ON area 2 and the power supply separation area 3 with the clock signal via the clock tree 10 by switching the SW 41. That is, the SW 41 is switched to the state in which the clock signal is supplied to the clock mesh 31. As a result, the drive target circuit of the Always-ON area 2 and the power supply separation area 3 is driven.

In this case, each of the SWs 51-54 is switched to the state in which between the clock mesh 21 and the clock mesh 31 are conducted. In this way, it is possible to considerably reduce the variation of the clock signal between the clock mesh 21 and the clock mesh 31 by directly conducting between the clock mesh 21 and the clock mesh 31 to each other. That is, it is possible to considerably reduce the clock skew between the Always-ON area 2 and the power supply separation area 3.

Note that, each of the SWs 51-54 may optimally have a resistance less than the resistance between the clock buffers 14 or 17 of the clock mesh 21 or 31. For example, in the clock mesh 21, the resistance between the clock buffers 14 is the resistance of the wire between the contact point with the clock buffer 14d that is a supplied point supplied the clock signal and the contact point with the clock buffer 14h (or 14c) that is a supplied point closest to the contact point with the clock buffer 14d. This enables to prevent the deviation of the clock signal by conducting the SWs 51-54, and practically conform all the clock meshes 21 and 31 to one clock mesh. Thus, it is possible to considerably reduce the clock skew between each of the area 2 and the area 3.

Next, when it is necessary to drive the drive target circuit of the power supply separation area 3, the SW 41 shuts off the clock signal supplied to the clock mesh 31. Furthermore, the semiconductor integrated circuit 1 shuts off the power supply supplied to the power supply separation area 3. In addition, the SWs 51-54 shuts off the clock signal conducted between the clock mesh 21 and the clock mesh 31. This makes that the clock signal is not supplied to the clock mesh 31 of the power supply separation area 3 via the clock mesh 21. Thus, it is possible to do not supply the normally unnecessary clock signal to the power supply separation area 3, thus do not consume the extra power supply.

As explained above, in accordance with the first exemplary embodiment of the present invention, it is possible to switch to the conduction or a shutoff of a signal transmitted between the clock mesh 21 of the Always-On area 2 and the clock mesh 31 of the power supply separation area 3 in which the power supply are supplied or shut off independently of the Always-ON area 2 by the SWs 51-54. This enables to conduct between the clock mesh 21 and the clock mesh 31, when the drive target circuits included in the areas 2 and 3 are driven. As a result, it is possible to reduce the clock skew between the area 2 and the area 3. Furthermore, when the drive target circuit of the one area 3 is not driven, it is possible to shut out between the clock mesh 31 of the area 3 and the clock mesh 21 of the area 2 in which the drive target circuit is driven. This prevents that the clock signal is supplied to the clock mesh 31 of the area 3 in which the drive target circuit is not driven via the clock mesh 21 of the area 2 in which the drive target circuit is driven, thus it is possible to reduce the power consumption. In addition, it is possible to reduce the power consumption by shutting off the power supply supplied to the area 3 in which the drive target circuit is not driven.

Furthermore, in accordance with the first exemplary embodiment of the present invention, between the clock mesh 21 and the clock mesh 31 that supplies the drive target circuit of the Always-ON area 2 and the power supply separation area 3 with the clock signal are directly conducted. This enables to considerably reduce the clock skew between the area 2 and the area 3 each other. In addition, in accordance with the exemplary embodiment of the present invention, it is possible to considerably reduce the clock skew without changing the configuration of the clock tree 10, for example, making the capacity of a clock buffer increase.

Furthermore, the effect that the clock skew is reduced and the power consumption is reduced by the first exemplary embodiment of the present invention is obtained not only a semiconductor integrated circuit that includes the areas in which the clock signal and the power supply are independently supplied or shut off. For example, the similar effect is obtained by applying the first exemplary embodiment of the present invention to a semiconductor integrated circuit that includes a first area and a second area in each of which the clock signal is independently supplied or shut off. The conduction or the shutoff of the clock signal transmitted between a clock mesh of the first area and a clock mesh of the second area are switched by applying the first exemplary embodiment of the present invention to this semiconductor integrated circuit. This enables to conduct between the clock mesh of the first area and the clock mesh of the second area, when the drive target circuit of the first area and the second area is driven. Thus, it is possible to reduce the clock skew between the first area and the second area. Furthermore, it is possible to shut off between the clock mesh of the first area and the clock mesh of the second area, when the second area is shut off from the clock signal as driving the drive target circuit of the second area is unnecessary. This prevents the clock signal is supplied to the clock mesh of the second area via the clock mesh of the first area, thus it is possible to reduce the power consumption.

### Second Exemplary Embodiment

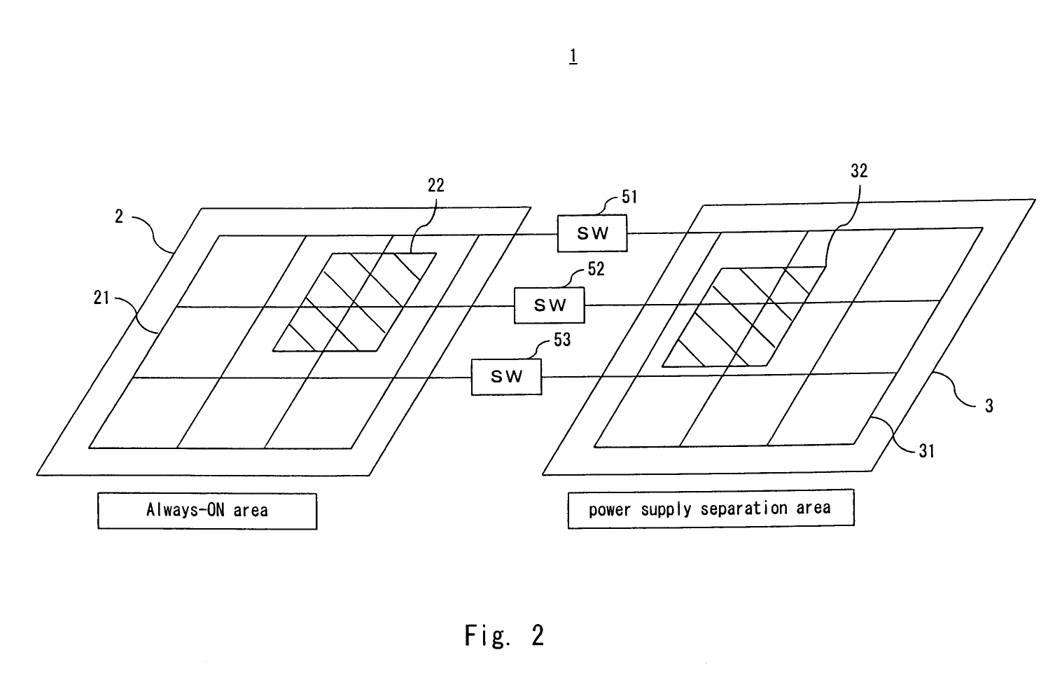

A configuration of a semiconductor integrated circuit in accordance with a second exemplary embodiment of the present invention is explained with reference to FIG. 2. FIG. 2 is a configuration diagram of a semiconductor integrated circuit in accordance with a second exemplary embodiment of the present invention.

The semiconductor integrated circuit 1 in accordance with a second exemplary embodiment of the present invention is a semiconductor integrated circuit 1 is, in accordance with a first exemplary embodiment of the present invention, in which the Always-ON area 2 includes a drive target circuit 25 and the power supply separation area 3 includes a drive target circuit 35.

In the second exemplary embodiment of the present invention, as shown in FIG. 2, the SWs 51-53 are laid out at a position that corresponds to the place laid out the drive target circuits 22 and 32 of the clock mesh 21 and the clock mesh 31.

As explained in the related arts, the reason why the clock skew is reduced is to prevent the malfunction caused by the deviation in operation timing for each of the drive target circuits 22 and 32 that operate by being supplied with the clock signal. Thus, it is possible to reduce the clock skew as intended by laying out the SWs 51-53 between places in which the drive target circuits 22 and 32 are densely laid out according to the degree of the density of the drive target circuit. The SWs 51-53 shuts out between the clock mesh 21 and the clock mesh 31. This prevents that the clock signal is supplied to the clock mesh 31 via the clock mesh 21. This enables to reduce the power consumption.

Thus, the second exemplary embodiment of the present invention enables to reduce the clock skew and reduce the power consumption as with the first exemplary embodiment of the present invention. Furthermore, the second exemplary embodiment of the present invention lays out the SWs 51-53 only between places in which the drive target circuits 22 and 32 are densely laid out according to the degree of the density of the drive target circuits 22 and 32. Thus, it is possible to cut back on the SW 54 laid out between other places in which the drive target circuits 22 and 32 are sparsely laid out. This enables to cut back on the element and wire resource, thus it is possible to reduce the cost. Note that, the SWs 51-53 may be laid out in any way according to the degree of the density of the drive target circuit. For example, as shown in FIG. 2, each of the SWs 51-53 may be laid out to conduct or shut off between a unit grid including the drive target circuit 25 of the clock mesh 21 and a unit grid including the drive target circuit 35 of the clock mesh 31. That is, each of the SWs 51-53 may be laid out between a unit grid located in an higher layer of a part that the drive target circuit 25 is densely laid out of the clock mesh 21 and a unit grid located in an higher layer of a part that the drive target circuit 32 is densely laid out of the clock mesh 31. Furthermore, the SW may not be laid out between a unit grid located in an higher layer of a part that the drive target circuit 25 is sparsely laid out of the clock mesh 21 and a unit grid located in an higher layer of a part that the drive target circuit 32 is sparsely laid out of the clock mesh 31. Note that, whether the SW is laid out on the border between a unit grid including the drive target circuit 25 and a unit grid including the drive target unit not including a drive target circuit as with the SW 53 may be arbitrarily determined.

Furthermore, number of the SW and position located the SW are not limited to that to conduct or shut out the grid points of the unit grids including the drive target circuits 22 and 32 of the clock meshes 21 and 31 as exemplified in above second exemplary embodiment. Note that, a unit grid is, if one of unit grids of the FIG. 1 is exemplified, the region that enclosed by the points connected the clock mesh 21 and each of the clock buffers 14c, 14d, 14g and 14h.

As explained above, in accordance with the second exemplary embodiment of the present invention, the SWs 51-53 are included according to the degree of the density of the drive target circuits 25 and 35 that included in each of the areas 2 and 3 in which the power supply is independently supplied or shut off. This enables to cut back on the SW 54, and cut back on the resource such as the element and wire composing the SW 54. Thus, it is possible to reduce the cost.

### Third Exemplary Embodiment

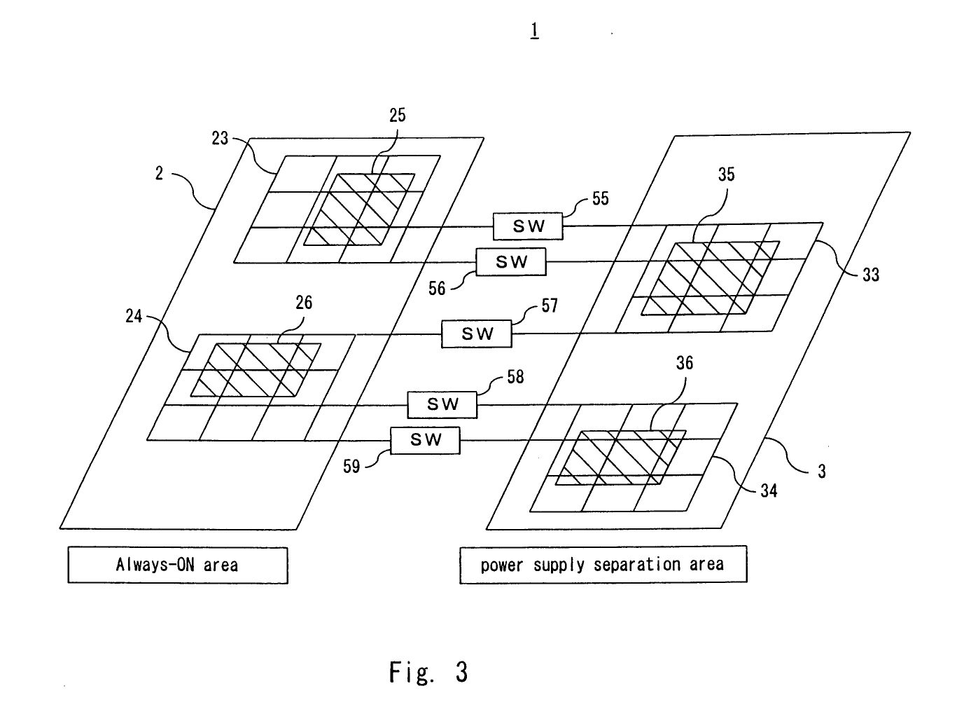

A configuration of a semiconductor integrated circuit in accordance with a third exemplary embodiment of the present invention is explained with reference to FIG. 3. FIG. 3 is a configuration diagram of a semiconductor integrated circuit in accordance with a third exemplary embodiment of the present invention.

The semiconductor integrated circuit 1 in accordance with a third exemplary embodiment of the present invention includes the Always-ON area 2 and the power supply separation area 3 as with the first exemplary embodiment of the present invention. The Always-ON area 2 includes clock meshes 23 and 24, and a drive target circuits 25 and 26. The power supply separation area 3 includes clock meshes 33 and 34, and the drive target circuits 35 and 36.

The clock meshes 23, 24, 33, and 34 are supplied with a clock signal from the clock tree (not shown) to reduce the clock skew each of the Always-ON area 2 and the power supply separation area 3.

The clock mesh 23 supplies the drive target circuit 25 with the clock signal supplied from the clock tree. The clock mesh 24 supplies the drive target circuit 26 with the clock signal supplied from the clock tree.

The clock mesh 33 supplies the drive target circuit 35 with the clock signal supplied from the clock tree. The clock mesh 34 supplies the drive target circuit 36 with the clock signal supplied from the clock tree.

The drive target circuit 25 and the drive target circuit 35 transmit data to each other. The drive target circuit 26 and the drive target circuit 35, 36 transmit data to each other.

Each of the SW 55 and 56 is a circuit that switches to the conduction or the shutoff of the clock signal transmitted between the clock mesh 23 and the clock mesh 33. The SW 57 is a circuit that switches to the conduction or the shutoff of the clock signal transmitted between the clock mesh 24 and the clock mesh 33.

Each of the SWs 58 and 59 is a circuit that switches to the conduction or the shutoff of the clock signal transmitted between the clock mesh 24 and the clock mesh 34.

The semiconductor integrated circuit 1 in accordance with a third exemplary embodiment of the present invention includes the SWs 55-29 to the conduction or the shutoff between the clock meshes that supply the drive target circuits transmitting data to each other with the clock signal. Note that, the drive target circuits transmits data to each other is a circuit such as CPU (Central Processing Unit) and RAM (Random Access Memory).

Note that, when there is a deviation of the clock signal supplied to each of the drive target circuits that transmit data to each other, the drive target circuits malfunctions by the deviation in operation timing of each of drive target circuits is occurred. Thus, it is possible to reduce the clock skew as intended by laying out the SWs 55-59 to conduct or shut off between the clock meshes that supply the drive target circuits transmitting data to each other with the clock signal. Furthermore, when driving the drive target circuits 35 and 36 are unnecessary, the SWs 55-59 shut out between the clock mesh 23 and the clock mesh 33, between the clock mesh 24 and the clock mesh 33, and between the clock mesh 24 and the clock mesh 34. This prevents that the clock signal is supplied to the clock meshes 33 and 34 via the clock meshes 24 and 34, thus it is possible to reduce the power consumption.

Thus, the third exemplary embodiment of the present invention enables to reduce the clock skew and reduce the power consumption as with the first exemplary embodiment of the present invention. Furthermore, the third exemplary embodiment of the present invention lays out the SWs 55-59 to conduct or shut off only between the clock meshes that supply the drive target circuits transmitting data to each other with the clock signal. This enables to cut back on the SW, thus cut back on the element and wire resource. Thus, it is possible to reduce the cost.

As explained above, in accordance with the third exemplary embodiment of the present invention, the SWs 55-59 are included to conduct or shut off between the clock meshes that supply the drive target circuits, transmitting data to each other with the clock signal, of the drive target circuits 25, 26, 35 and 36 that are included in each of the areas 2 and 3 in which the power supply are independently supplied or shut off. This enables to cut back on the SW, and cut back on the resource such as the element and wire composing the SW. Thus, it is possible to reduce the cost.

Furthermore, in accordance with the first to third exemplary embodiment of the present invention, it is possible to lay out a drive target circuits having arbitrary function, such as CPU and RAM, on each of the clock meshes 23, 24, 33 and 34. That is, in the first to third exemplary embodiment of the present invention, even if the deviation of the clock signal be wanted to occur, the drive target circuits having arbitrary function each of the clock meshes are individually designed without the drive target circuits is consolidated to a clock mesh. This enables to easily design a circuit.

### Fourth Exemplary Embodiment

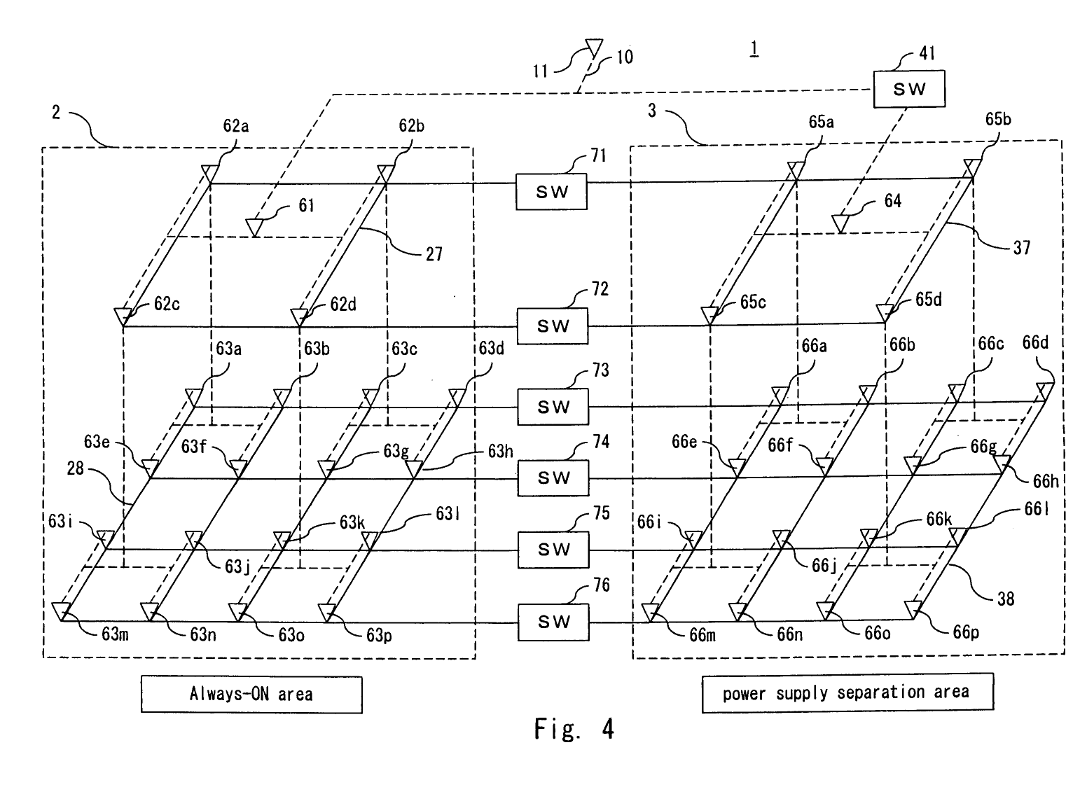

A configuration of a semiconductor integrated circuit in accordance with a fourth exemplary embodiment of the present invention is explained with reference to FIG. 4. FIG. 4 is a configuration diagram of a semiconductor integrated circuit in accordance with a fourth exemplary embodiment of the present invention.

A semiconductor integrated circuit 1 includes a Always-ON area 2, a power supply separation area 3, a clock tree 10, a clock root buffer 11, SW 41 and SWs 71, 72, 73, 74, 75, and 76.

The clock tree 10, in a branch in the Always-ON area 2, includes clock buffer 61 in the next stage of the clock root buffer 11, clock buffers 62a-62d in the next stage of the clock buffer 61, and clock buffers 63a-63p in the next stage of the clock buffers 62. The clock buffers 62a-62d are referred to as “clock buffers 62”, the clock buffers 63a-63p are referred to as “clock buffers 63”.

The clock tree 10, in a branch in the power supply separation area 3, includes a clock buffer 64 in the next stage of the clock root buffer 11, clock buffers 65a-65d the next stage of the clock buffer 64, and lock buffers 66a-66p of the next stage of the clock buffers 65. The clock buffers 65a-65d are referred to as “clock buffers 65”, the clock buffers 66a-66p are referred to as “clock buffers 66”. Note that, branch corresponds to the first wire or the second wire.

Next, the elements of a semiconductor integrated circuit in accordance with a fourth exemplary embodiment of the present invention are explained.

The Always-ON area 2, the power supply separation area 3 and the clock root buffer 11 are same as them in the first exemplary embodiment of the present invention.

The clock tree 10 supplies the clock mesh 27 with the clock signal supplied from the clock root buffer 11 via the clock buffers 61 and 62. The clock tree 10 supplies the clock mesh 28 with the clock signal via clock mesh 27 and clock buffers 63. The clock tree 10 supplies the clock mesh 37 with the clock signal supplied from the clock root buffer 11 via the clock buffers 64 and 65. The clock tree 10 supplies the clock mesh 38 with the clock signal via the clock mesh 37 and the clock buffers 66. That is, a semiconductor integrated circuit 1 in accordance with a fourth exemplary embodiment of the present invention includes the clock meshes 27 and 28, and the clock meshes 37 and 38 in a way that they are arranged in hierarchic structure.

Each of the clock buffers 61-66 is a circuit that adjusts the phase of the clock signal transmitted by the clock tree 10.

The clock mesh 27 supplies the clock buffers 63 with the clock signal supplied from the clock buffers 62.

The clock mesh 37 supplies the clock buffers 66 with the clock signal supplied from the clock buffers 65.

The clock mesh 28 supplies the drive target circuit included in the Always-ON area 2 with the clock signal supplied from the clock buffers 63.

The clock mesh 38 supplies the drive target circuit included in the power supply separation area 3 with the clock signal supplied from the clock buffers 66.

The SW 41 is a circuit that switches to the supply or the shutoff of the power supply supplied to the clock meshes 37 and 38. The SW 41 shuts off the clock signal supplied to the clock meshes 37 and 38, when it is necessary to drive the drive target circuit of the power supply separation area 3.

Each of the SWs 71 and 72 is a circuit that switches to the conduction or the shutoff of the clock signal transmitted between the clock mesh 27 and the clock mesh 37. Each of the SWs 73-76 is a circuit that switches to the conduction or the shutoff of the clock signal transmitted between the clock mesh 28 and the clock mesh 38.

Next, a processing of a semiconductor integrated circuit in accordance with a fourth exemplary embodiment of the present invention is explained.

When the Always-ON area 2 and the power supply separation area 3 are driven, the semiconductor integrated circuit 1 supplies the Always-ON area 2 and the power supply separation area 3 with the power supply. The semiconductor integrated circuit 1 supplies the Always-ON area 2 and the power supply separation area 3 with the clock signal via the clock tree 10 by switching the SW 41. That is, the SW 41 is switched to the state in which the clock signal is supplied to the clock meshes 37 and 38. As a result, the drive target circuit of the Always-ON area 2 and the power supply separation area 3 is driven.

In this case, the SWs 71, 72 are switched to the state in which between the clock mesh 27 and the clock mesh 37 are conducted. Furthermore, the SWs 73-76 are switched to the state in which between the clock mesh 28 and the clock mesh 38 are conducted. In this way, it is possible to considerably reduce the variation of the clock signal between the clock mesh 28 and the clock mesh 38 by conducting between the clock mesh 28 and the clock mesh 38 to each other. In addition, it is possible to considerably reduce the variation of the clock signal between the clock mesh 27 and the clock mesh 37 by conducting the clock mesh 27 and the clock mesh 37 of higher layer to each other of the clock meshes 27, 28, 37, and 38 arranged in hierarchic structure.

That is, in the fourth exemplary embodiment of the present invention, the clock signal reduced the clock skew at the clock mesh 27 and 37 of higher layer is supplied to the clock meshes 28 and 38 of lower layer. Furthermore, in the fourth exemplary embodiment of the present invention, the clock skew in the clock meshes 28 and 38 of lower layer is reduced. This enables to considerably reduce the clock skew between the Always-ON area 2 and the power supply separation area 3, compared with the first exemplary embodiment of the present invention.

Next, when it is necessary to drive the drive target circuit of the power supply separation area 3, the SW 41 shuts off the clock signal supplied to the clock meshes 37 and 38. Furthermore, the semiconductor integrated circuit 1 shut off the power supply supplied to the power supply separation area 3. Moreover, the SWs 71 and 72 shut off between the clock mesh 27 and the clock mesh 37. In addition, the SWs 73-76 shut off between the clock mesh 28 and the clock mesh 38. This makes that the clock signal is not supplied to the clock meshes 37 and 38 of the power supply separation area 3 via the clock meshes 27 and 28. Thus, it is possible to do not supply the normally unnecessary clock signal to the power supply separation area 3, and do not consume the extra power supply.

As explained above, in accordance with the fourth exemplary embodiment of the present invention, the connection between the clock meshes 27 and 28 in the Always-On area 2 and the clock meshes 37 and 38 in the power supply separation area 3, in which the supply and the shutoff of the power supply can be controlled independently of the Always-On 2, can be switched between conduction and shutoff by the SW 71 to 76. Furthermore, the semiconductor integrated circuit in accordance with a fourth exemplary embodiment of the present invention includes the clock meshes arranged in hierarchic structure that includes the clock meshes 27 and 37 of higher layer and the clock meshes 28 and 38 of lower layer supplied with the clock signal from the clock meshes 27 and 37.

This enables to conduct between the clock mesh 27 and the clock mesh 37, when the drive target circuits included in the areas 2 and 3 are driven. Thus, it is possible to reduce the clock skew between the areas 2 and 3 in which the power supply are independently supplied or shut off. Furthermore, when the drive target circuit of the one area 3 is not driven, it is possible to shut out between the clock meshes 27 and 28 of the area 3 and the clock meshes 37 and 38 of the area 2 in which the drive target circuit is driven. This prevents that the clock signal is supplied to the clock meshes 37 and 38 of the area 3 in which the drive target circuit is not driven via the clock meshes 27 and 28 of the area 2 in which the drive target circuit is driven, thus it is possible to reduce the power consumption.

The present invention is not limited to the above exemplary embodiment, but is modified as appropriate within the scope of the present invention.

For example, the scope of the present invention is not limit to a semiconductor integrated circuit in which the clock signal and the power supply are independently supplied or shut off only in a power supply separation circuit as the semiconductor integrated circuit exemplified in above exemplary embodiment. The present invention may apply to a semiconductor integrated circuit in which the clock signal and the power supply are independently supplied or shut off in all of the areas.

Furthermore, number of areas is limit to two as the Always-ON area and the power supply separation area exemplified in above exemplary embodiment. For example, a semiconductor integrated circuit may include two or more of plurality areas, and may include the SW to conduct or shut off between clock meshes of areas in which the power supply is independently supplied or shut off of the those areas.

In addition, the areas of the above exemplary embodiment may be included in a chip, and may be included in a different chip.

The first to fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor integrated circuit comprising:
a first wire that is supplied with a clock signal;
a second wire that is supplied with the clock signal, the clock signal is supplied or shut off independently of the clock signal supplied to the first wire;
a first area that includes a first mesh shape wire supplied with the clock signal from the first wire;
a second area that includes a second mesh shape wire supplied with the clock signal from the second wire; and
a switching circuit that switches to a conduction or a shut off of a signal transmitted between the first mesh shape wire and the second mesh shape wire.

2. The semiconductor integrated circuit according to claim 1, wherein
the first area includes a first drive target circuit supplied with the clock signal from the first mesh shape wire,
the second area includes a second drive target circuit supplied with the clock signal from the second mesh shape wire, and
the semiconductor integrated circuit has the switching circuit to conduct between a unit grid of the first mesh shape wire located in a higher layer of a part in which the first drive target circuit is densely laid out and a unit grid of the second mesh shape wire located in a higher layer of a part in which the second drive target circuit is densely laid out.

3. The semiconductor integrated circuit according to claim 1, wherein
the first area includes a first drive target circuit supplied with the clock signal from the first mesh shape wire,
the second area includes a second drive target circuit supplied with the clock signal from the second mesh shape wire, and
the first drive target circuit and the second drive target circuit transmit data to each other.

4. The semiconductor integrated circuit according to claim 1, wherein
the first area includes a first supplied point and a second supplied point in which the clock signal is supplied to the first mesh shape wire from the first wire, and
a resistance of the switching circuit of the conducting state is smaller than the wiring resistance of the first supplied point and the second supplied point of the first mesh shape wire.

5. The semiconductor integrated circuit according to claim 1, wherein
the first mesh shape wire includes a mesh shape wire of a higher layer and a mesh shape wire in a lower layer,
the second mesh shape wire includes a mesh shape wire of a higher layer and a mesh shape wire in a lower layer, and
the switching circuit includes a circuit that switches to the conduction or the shutoff of a signal transmitted between the first mesh shape wire and the second mesh shape wire of the higher layer and a circuit that switches to the conduction or the shutoff of a signal transmitted between the first mesh shape wire and the second mesh shape wire of the lower layer.

6. The semiconductor integrated circuit according to claim 1, wherein
the first and second areas are areas in each of which the power supply is supplied or shut off independently of each other.

7. The semiconductor integrated circuit according to claim 1, further comprising:
a third wire that the clock signal is supplied or shut off independently of the clock signal supplied to at least of the first wire and the second wire in, the third wire is supplied with the clock signal,
a third area that includes a third mesh shape wire supplied with the clock signal from the third wire, and
a switching circuit that switches to the conduction or the shutoff of a signal transmitted between the first mesh shape wire or the second mesh shape wire supplied with the clock signal from the first wire or the second wire in which the clock signal is supplied or shut off independently of the third wire and the third mesh shape wire.

8. The semiconductor integrated circuit according to claim 1, wherein the first wire and the second wire is a tree shape wire.

9. The semiconductor integrated circuit according to claim 1, wherein the first and second areas are included in a chip.
